(19) United States
(12) Patent Application Publication
(10) Pub. No.: US 2025/0226232 A1
(43) Pub. Date: Jul. 10, 2025

(54) IMPRINT APPARATUS, IMPRINT METHOD, AND ARTICLE MANUFACTURING METHOD

(71) Applicant: CANON KABUSHIKI KAISHA, Tokyo (JP)

(72) Inventors: YU NOMURA, Tochigi (JP); KAZUKI NAKAGAWA, Tochigi (JP)

(21) Appl. No.: 18/983,645

(22) Filed: Dec. 17, 2024

(30) Foreign Application Priority Data
Jan. 9, 2024 (JP) 2024-001497

(51) Int. Cl. H01L 21/3105; G03F 7/00

(52) U.S. Cl. CPC H01L 21/31058; G03F 7/0002

(57) ABSTRACT

An imprint apparatus is provided. The apparatus includes a supplier configured to supply a gas to a space between a mold and an imprint material on a shot region, an irradiator configured to perform light irradiation, and a controller. A plurality of shot regions on a substrate include a full shot region having a size where a pattern region of the mold is fully transferred, and a partial shot region where only a part of the pattern region is transferred because of being located in an outer peripheral portion of the substrate. When performing an imprint process on the partial shot region, the controller reduces a supply amount of a gas from the supplier and increases an amount of irradiation light from the irradiator as compared to a case of performing the imprint process on the full shot region.

### BACKGROUND OF THE INVENTION

### Field of the Invention

The present invention relates to an imprint apparatus, an imprint method, and an article manufacturing method.

### Description of the Related Art

As the requirements of microfabrication for semiconductor devices grow, not only conventional photolithography techniques but also a microfabrication technique for molding an imprint material on a substrate using a mold and curing it to form a pattern on the substrate has received a great deal of attention. This technique is called an imprint technique, and can form a fine pattern on a several nanometer order on a substrate.

One of the imprint techniques is, for example, a photo-curing method. According to the photo-curing method, a mold is brought into contact with a photo-curable imprint material applied on a substrate (contact step), the imprint material is cured by light irradiation (curing step), and the mold is separated from the cured imprint material (separation step), thereby forming a pattern on the substrate.

In the contact step, air (residual gas) between the mold and the imprint material can enter the uncured imprint material as bubbles and generate unfilled defects (pattern defects). Therefore, it is necessary to suppress residual bubbles. Japanese Patent Laid-Open No. 2007-509769 describes that residual bubbles are suppressed by filling a space between a mold and a substrate with a gas having high solubility, high diffusibility, or both characteristics with respect to an imprint material.

In order to obtain more patterns on the substrate to further improve productivity, it is required to perform an imprint process on the outer peripheral region (partial shot region) of the substrate as well. As in a photolithography step using light, an imprint step using the imprint technique generally involves overlapping, on a pattern or structure formed on a substrate in advance, a new pattern to be formed. Accordingly, the substrate may be warped or have a step in the outer peripheral region of the substrate. Further, depending on the structure of a substrate chuck for holding the substrate and the pressure of vacuum exhaust used to hold the substrate, the substrate may be bent or locally distorted. Hence, the substrate in the imprint step using the imprint technique is not always flat. The influence of the bend or step of the substrate is especially large in the outer peripheral region of the substrate. Therefore, when performing the imprint process on the outer peripheral region of the substrate, the imprint material arranged near the outermost periphery may not come into complete contact with the mold and the imprint material may adhere to the mold in the contact step. If the imprint material adhering to the mold is cured by light irradiation and remains, the residual imprint material is transferred to the substrate during the imprint process on the next shot region, and this can cause a defect.

In the imprint process on the outer peripheral region of the substrate, if the imprint process is performed in an atmosphere with sufficient oxygen, even if the imprint material adhering to the mold is irradiated with light, oxygen inhibits curing of the imprint material. In the imprint process on the next shot region, if the imprint material adhering to the mold is uncured, the uncured imprint material is molded with the imprint material on the next shot region. However, in this case, the variation in pattern dimension increases as compared to a case of performing the imprint process while filling the gap between the substrate and the mold with a gas having high solubility, high diffusibility, or both characteristics.

### SUMMARY OF THE INVENTION

The present invention provides, for example, an imprint apparatus advantageous in achieving reduction of defects generated by an imprint process, and reduction of a variation in pattern dimension.

The present invention in its one aspect provides an imprint apparatus that performs, on each of a plurality of shot regions on a substrate, an imprint process of forming a pattern on a shot region by curing an imprint material by light irradiation while a mold is in contact with the imprint material on the shot region, including a supplier configured to supply a gas to a space between the mold and the imprint material on the shot region, an irradiator configured to perform the light irradiation, and a controller configured to control the supplier and the irradiator, wherein the plurality of shot regions include a full shot region having a size where a pattern region of the mold is fully transferred, and a partial shot region where only a part of the pattern region is transferred because of being located in an outer peripheral portion of the substrate, and when performing the imprint process on the partial shot region, the controller reduces a supply amount of a gas from the supplier and increases an amount of irradiation light from the irradiator as compared to a case of performing the imprint process on the full shot region.

Further features of the present invention will become apparent from the following description of exemplary embodiments (with reference to the attached drawings).

### BRIEF DESCRIPTION OF THE DRAWINGS

FIG. 1 is a view showing the arrangement of an imprint apparatus;

FIG. 2 is a view exemplarily showing the shot layout of a substrate;

FIGS. 3A and 3B are views each showing a conventional imprint method;

FIGS. 4A and 4B are views each showing an imprint method in an embodiment;

FIGS. 5A and 5B are views each showing an example of the structure obtained by an imprint process;

FIGS. 6A to 6F are views each showing an example of the imprint order and distortion generation result;

FIG. 7 is a view showing the number of shot regions where distortion occurred relative to each imprint order; and

FIG. 8 is a view for explaining an article manufacturing method.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

### First Embodiment

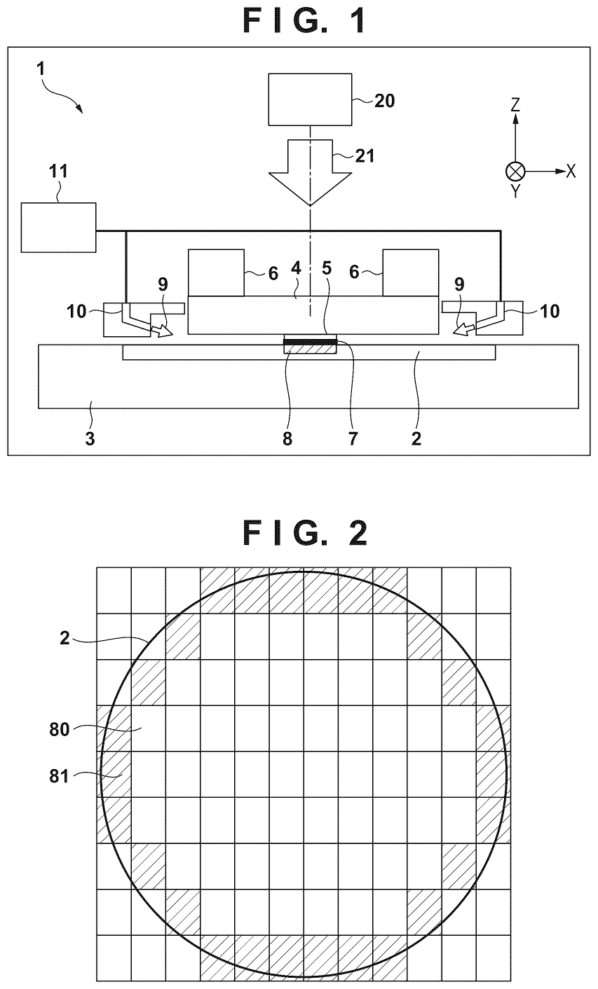

FIG. 1 is a view showing the arrangement of an imprint apparatus 1 in an embodiment. In the specification and the drawings, directions will be indicated on an XYZ coordinate system in which a horizontal surface is defined as the X-Y plane. In general, a substrate 2 serving as an object to be processed is placed on a substrate stage 3 such that the surface of the substrate 2 is parallel to the horizontal surface (X-Y plane). Therefore, in the following description, the directions orthogonal to each other in a plane along the surface of the substrate 2 (the substrate placement surface of the substrate stage 3) are the X-axis and the Y-axis, and the direction perpendicular to the X-axis and the Y-axis is the Z-axis. Further, in the following description, directions parallel to the X-axis, the Y-axis, and the Z-axis of the XYZ coordinate system are referred to as the X direction, the Y direction, and the Z direction, respectively, and a rotational direction around the X-axis, a rotational direction around the Y-axis, and a rotational direction around the Z-axis are referred to as the θX direction, the θY direction, and the θZ direction, respectively.

First, an outline of the imprint apparatus according to the embodiment will be described. The imprint apparatus is an apparatus that brings a mold into contact with an imprint material supplied onto a substrate and applies curing energy to the imprint material, thereby forming a pattern of a cured product to which the concave-convex pattern of the mold is transferred.

As the imprint material, a curable composition (to be also referred to as a resin in an uncured state) to be cured by receiving curing energy is used. As the curing energy, an electromagnetic wave or heat can be used. The electromagnetic wave can be, for example, light selected from the wavelength range of 10 nm (inclusive) to 1 mm (inclusive), for example, infrared light, a visible light beam, or ultraviolet light. The curable composition can be a composition cured by light irradiation or heating. Among compositions, a photo-curable composition cured by light irradiation contains at least a polymerizable compound and a photopolymerization initiator, and may further contain a nonpolymerizable compound or a solvent, as needed. The nonpolymerizable compound is at least one material selected from the group consisting of a sensitizer, a hydrogen donor, an internal mold release agent, a surfactant, an antioxidant, and a polymer component. The imprint material can be arranged, by an imprint material supply apparatus (not shown), on the substrate in the form of droplets or in the form of an island or film formed by connecting a plurality of droplets. The viscosity (the viscosity at 25° C.) of the imprint material can be, for example, 1 mPa·s (inclusive) to 100 mPa·s (inclusive). As the material of the substrate, for example, glass, a ceramic, a metal, a semiconductor, a resin, or the like can be used. A member made of a material different from the substrate may be provided on the surface of the substrate, as needed. The substrate is, for example, a silicon wafer, a compound semiconductor wafer, or silica glass.

The imprint apparatus 1 is an apparatus that is used in the manufacture of a device such as a semiconductor device, and forms a pattern of an imprint material on a substrate by molding the imprint material on the substrate with a mold. In this embodiment, the imprint apparatus 1 is configured to perform an imprint process by a photo-curing method. Hence, the imprint apparatus 1 performs, on each of a plurality of shot regions on a substrate, an imprint process of forming a pattern on the shot region by curing the imprint material by light irradiation in a state in which the imprint material on the shot region is in contact with the mold. The imprint apparatus 1 can include a light irradiator 20, a mold holder 6, the substrate stage 3, and a gas supplier 10.

During the imprint process, the light irradiator 20 irradiates an imprint material 7 with ultraviolet light 21. The light irradiator 20 can include an optical element that adjusts the ultraviolet light 21 emitted from a light source to light suitable for the imprint process.

A mold 4 has, for example, a square outer peripheral shape, and a surface thereof to face the substrate 2 includes a pattern portion 5 (pattern region) where, for example, a concave-convex pattern such as a circuit pattern to be transferred to the substrate is three-dimensionally formed. The material of the mold 4 can transmit the ultraviolet light 21. In this embodiment, the material of the mold 4 is, for example, quartz.

The mold holder 6 includes a driving mechanism for holding the mold 4 and moving the mold 4. The mold holder 6 attracts, by a vacuum suction force or an electrostatic force, the outer peripheral region of the surface of the mold 4 to be irradiated with the ultraviolet light 21, thereby holding the mold 4.

The driving mechanism of the mold holder 6 can move the mold 4 in the Z direction to selectively perform contact and separation between the mold 4 and the imprint material 7 on the substrate 2. The driving mechanism of the mold holder 6 can also move the mold 4 in the X and Y directions to align the mold 4 and the substrate 2. To cope with the highly precise positioning of the mold 4, the driving mechanism of the mold holder 6 may be formed from a plurality of driving systems such as a coarse driving system and a fine driving system. The driving mechanism of the mold holder 6 may be configured to be capable of moving the mold 4 not only in the X, Y, and Z directions but also in the θX, θY, and θZ directions. Note that the contact and separation operations between the mold 4 and the imprint material 7 on the substrate 2 may be performed by moving the mold 4 in the Z direction by the mold holder 6, or moving the substrate stage 3 in the Z direction. Alternatively, the contact and separation operations between the mold 4 and the imprint material 7 on the substrate 2 may be performed by moving both the mold holder 6 and the substrate stage 3. The movement may be relative movement. In this manner, in this embodiment, the mold holder 6 and the substrate stage 3 constitute a driver that relatively drives the mold 4 and the substrate 2 to change the spacing between the mold 4 and the substrate 2.

The substrate 2 is, for example, a single-crystal silicon substrate or a Silicon on Insulator (SOI) substrate, and its surface to be processed is coated with the imprint material 7 which is formed into a pattern using the pattern portion 5 formed on the mold 4.

The imprint material 7 can be applied, onto the substrate 2, in a droplet shape or in an island or film shape formed by connecting a plurality of droplets using a liquid injection head of an imprint material supply apparatus (not shown). Alternatively, the imprint material 7 may be applied in a film shape onto the substrate 2 by a spin coater or a slit coater. The imprint material 7 is a photo-curable resin having a property of being cured by receiving the ultraviolet light 21, and can be appropriately selected in accordance with various kinds of conditions for a semiconductor device manufacturing process or the like. The photo-curable resin contains at least a polymerizable compound and a photopolymerization initiator, and may contain a nonpolymerizable compound or a solvent, as needed. In this embodiment, the imprint material 7 is applied, in the form of a plurality of droplets, onto a shot region 8 on the substrate 2 by the liquid injection head (not shown).

The substrate stage 3 is configured to hold and move the substrate 2. The substrate stage 3 can include a stage driving mechanism (not shown) that enables movement in each axis direction. The stage driving mechanism may be formed from a plurality of driving systems such as a coarse driving system and a fine driving system to position the substrate 2 in the X and Y directions. With this, the substrate stage 3 can move the substrate 2 in the X and Y directions to align the mold 4 and the shot region 8 when bringing the mold 4 into contact with the imprint material 7 on the shot region 8 on the substrate 2. The substrate stage 3 may further include a driving mechanism for Z-direction position adjustment and a driving mechanism for moving the substrate 2 in each of the θX, θY, and θZ directions.

After positioning the mold 4 and the substrate 2 in a predetermined positional relationship, for example, the mold holder 6 moves in the −Z direction to bring the pattern portion 5 of the mold 4 into contact with the imprint material 7 on the shot region 8. In this state, the light irradiator 20 emits the ultraviolet light 21 to the imprint material 7. This cures the imprint material 7. Thereafter, the mold holder 6 moves in the +Z direction to separate the mold 4 from the imprint material 7. Thus, the pattern of the imprint material is formed on the substrate 2. The above is the contents of the imprint process for one shot region.

The gas supplier 10 supplies a gas 9 to a space between the mold 4 and the substrate 2, thereby replacing the gas between the mold 4 and the substrate 2 with the gas 9. If bubbles are included between the mold 4 and the imprint material 7 when curing the imprint material 7, the imprint material 7 does not fill in the bubble portions, and a defect can be generated in the pattern of a cured product. The gas 9 to be supplied by the gas supplier 10 can include a permeable gas that is permeated through at least one of the mold 4 and the imprint material 7 while the mold 4 and the imprint material 7 are in contact with each other. As the permeable gas, for example, a noble gas such as helium (He) is used. The gas supplier 10 is arranged around the mold 4. The supply of the gas 9 is controlled by a controller 11.

The controller 11 comprehensively controls the respective units of the imprint apparatus 1. The controller 11 can be formed from, for example, an information processing apparatus (computer) that includes a processor such as a Central Processing Unit (CPU) and a storage unit such as a memory. Note that the controller 11 may be arranged in the housing of the imprint apparatus 1, or may be arranged outside the housing of the imprint apparatus 1. The controller 11 arranged outside the housing of the imprint apparatus 1 may be implemented by, for example, a computer that functions as a control server connected to the imprint apparatus 1 by a network.

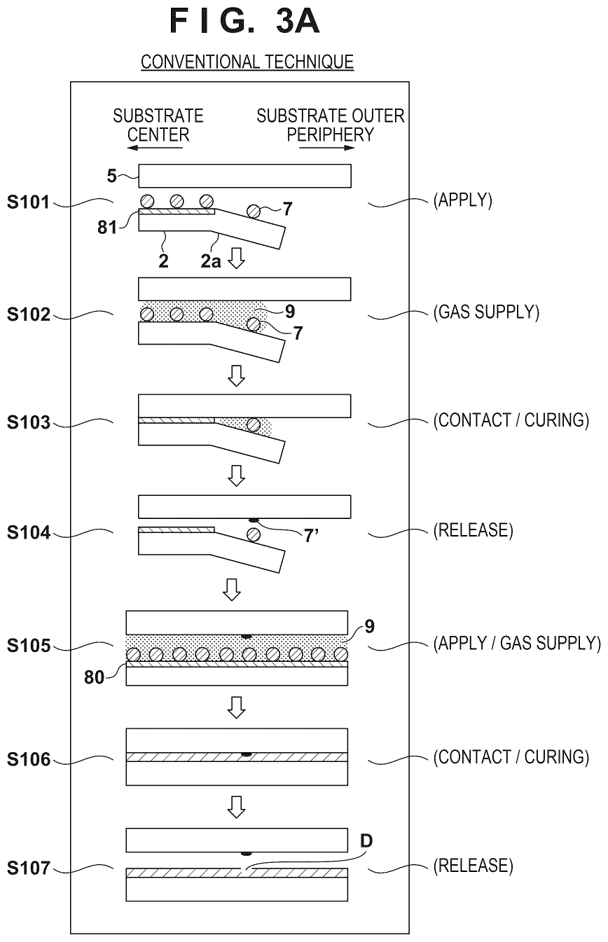

A plurality of shot regions are formed on the substrate 2, and the imprint process is executed on each of the plurality of shot regions. FIG. 2 shows the general substrate 2 having a circular shape, and an example of the layout (shot layout) of a plurality of shot regions formed thereon. The plurality of shot regions can include full shot regions 80 each having the size where the pattern portion 5 of the mold 4 is fully transferred, and partial shot regions 81 (omission shot regions) where only a part of the pattern portion 5 of the mold 4 is transferred because of being located in the outer peripheral portion of the substrate 2. A shot region that has no “omission” but has a corner only contacting the outer periphery of the substrate and a shot region near the outer periphery of the substrate may also be classified as the partial shot regions 81. The substrate 2 can include a valid region where a chip is to be formed, and an invalid region outside the valid region where no chip is to be formed. For example, a region within a predetermined distance from the outer peripheral edge of the substrate can be regarded as the invalid region that is not targeted by the imprint process because it is readily influenced by a process in a previous step, or according to the standard of a substrate storage apparatus. A shot region partially overlapping the invalid region may also be classified as the partial shot region 81. In this meaning, it may be understood that the partial shot region 81 is a shot region defined by the outer edge of the valid region. In order to obtain more chips from one substrate, the imprint process is also performed on the partial shot region 81.

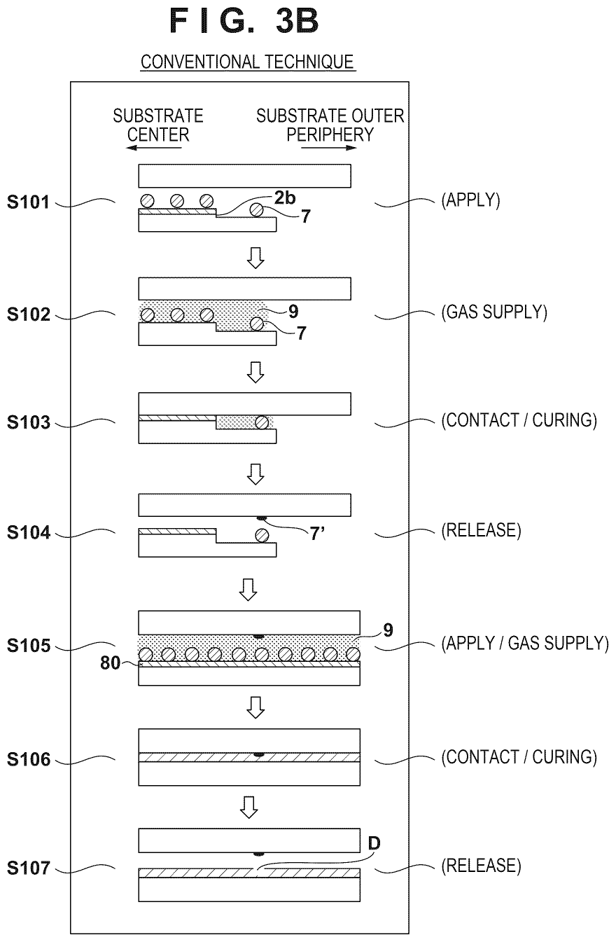

With reference to FIGS. 3A and 3B, a conventional imprint method will be described. Here, a case will be described in which the imprint process is first performed on the partial shot region 81 and then the imprint process is performed on the full shot region 80. The substrate 2 is held by a substrate chuck (not shown) on the substrate stage 3. The substrate chuck holds the substrate 2 by, for example, vacuum suction. Therefore, depending on the shape of the substrate chuck and the pressure of vacuum suction, the outer peripheral portion of the substrate 2 can particularly be bent. In addition, since the substrate 2 undergoes preprocessing such as patterning by photolithography before being supplied to the imprint apparatus 1, steps can be generated in the outer peripheral portion of the substrate 2. FIG. 3A shows a case where a bend 2a is generated in the outer peripheral portion of the substrate 2, and FIG. 3B shows a case where a step 2b is generated in the outer peripheral portion of the substrate 2.

In step S101, the controller 11 controls an imprint material supply apparatus (not shown) to arrange (apply) the imprint material 7 in the partial shot region 81 as the imprint target of the substrate 2 (apply step). In the apply step, in order to supply a sufficient amount of the imprint material 7 to the partial shot region 81, the imprint material 7 can also be applied to the region having the bend 2a or the step 2b. After that, the controller 11 controls the substrate stage 3 to position the partial shot region 81 with the imprint material 7 applied thereon below the pattern portion 5.

In order to prevent unfilling of the imprint material due to confinement of bubbles in a contact step, the controller 11 controls the gas supplier 10 to supply the gas 9 (supply step) in step S102 before the contact step. With this, the air between the pattern portion 5 and the substrate 2 is replaced with the gas 9.

In step S103, the controller 11 controls the mold holder 6 to bring the pattern portion 5 into contact with the imprint material 7 on the partial shot region 81 (contact step). With this, the imprint material 7 is filled in the pattern portion 5. At this time, the imprint material 7 applied in the region having the bend 2a or the step 2b can also contact the pattern portion 5, but the degree of contact can be insufficient for the entire imprint material 7 to remain on the substrate 2 upon releasing the mold. Thereafter, the controller 11 causes the light irradiator 20 to emit the ultraviolet light 21. The ultraviolet light 21 is applied to the imprint material 7 via the mold 4. This cures the imprint material 7 (curing step).

In step S104, the controller 11 controls the mold holder 6 to separate (release) the pattern portion 5 from the cured imprint material 7 (separation step). At this time, since the imprint material 7 applied in the region having the bend 2a or the step 2b is in insufficient contact with the pattern portion 5, an imprint material 7′, which is a part of the imprint material 7, remains adhering to the pattern portion 5 upon releasing the mold. The imprint material 7′ remaining on the surface of the pattern portion 5 has been cured by the ultraviolet light 21, and remains intact on the surface of the pattern portion 5. As a result, the imprint process on the next shot region is performed while the imprint material 7′ remains on the surface of the pattern portion 5.

In subsequent steps S105 to S107, the imprint process is performed on the full shot region 80. In step S105, the controller 11 controls the imprint material supply apparatus (not shown) to arrange (apply) the imprint material 7 in the full shot region 80 as the imprint target of the substrate 2 (apply step). At this time, the cured imprint material 7′ remains on the pattern portion 5. After that, the controller 11 controls the substrate stage 3 to position the full shot region 80 with the imprint material 7 applied thereon below the pattern portion 5. Then, the controller 11 controls the gas supplier 10 to supply the gas 9 (supply step). With this, the air between the pattern portion 5 and the substrate 2 is replaced with the gas 9.

In step S106, the controller 11 controls the mold holder 6 to bring the pattern portion 5 into contact with the imprint material 7 on the full shot region 80 (contact step). With this, the imprint material 7 is filled in the pattern portion 5. Thereafter, the controller 11 causes the light irradiator 20 to emit the ultraviolet light 21. The ultraviolet light 21 is applied to the imprint material 7 via the mold 4. This cures the imprint material 7 (curing step).

In step S107, the controller 11 controls the mold holder 6 to separate (release) the pattern portion 5 from the cured imprint material 7 (separation step). At this time, insufficient filling and a pattern formation defect occur in the portion that was in contact with the imprint material 7′ remaining on the pattern portion 5. As a result, in the imprint material 7 molded through the separation step in step S107, a defect D is generated in the contact portion of the remaining imprint material 7′.

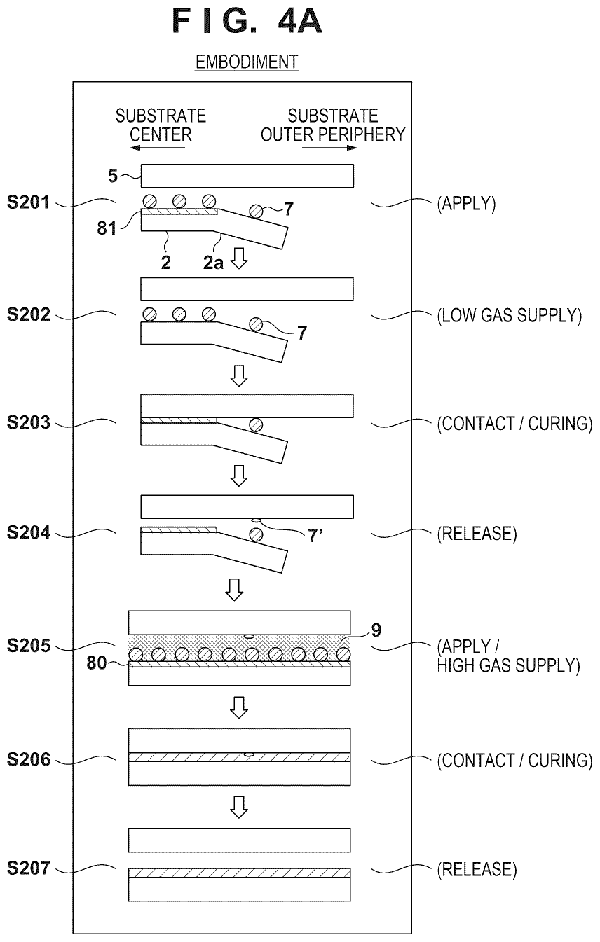

To prevent this, in this embodiment, when performing the imprint process on the partial shot region 81, as compared to the imprint process performed on the full shot region 80, the supply amount of the gas 9 in the supply step is reduced and the amount of irradiation light in the curing step is increased. With reference to FIGS. 4A and 4B, the imprint method according to this embodiment will be described. FIG. 4A shows a case where the bend 2a is generated in the outer peripheral portion of the substrate 2, and FIG. 4B shows a case where the step 2b is generated in the outer peripheral portion of the substrate 2. Here, a case will be described in which the imprint process is first performed on the partial shot region 81 and then the imprint process is performed on the full shot region 80, as in FIGS. 3A and 3B.

In step S201, the controller 11 controls an imprint material supply apparatus (not shown) to arrange (apply) the imprint material 7 in the partial shot region 81 as the imprint target of the substrate 2 (apply step). In the apply step, in order to supply a sufficient amount of the imprint material 7 to the partial shot region 81, the imprint material 7 can also be applied to the region having the bend 2a or the step 2b. After that, the controller 11 controls the substrate stage 3 to position the partial shot region 81 with the imprint material 7 applied thereon below the pattern portion 5.

In step S202, the controller 11 controls the gas supplier 10 to supply the gas 9 (supply step). Here, when performing the imprint process on the partial shot region 81, the supply amount of the gas 9 is reduced as compared to the case of performing the imprint process on the full shot region 80. Reducing the supply amount of the gas 9 can include setting the supply amount of the gas 9 to zero (that is, turning off the supply of the gas from the gas supplier 10).

In step S203, the controller 11 controls the mold holder 6 to bring the pattern portion 5 into contact with the imprint material 7 on the partial shot region 81 (contact step). With this, the imprint material 7 is filled in the pattern portion 5. However, in the partial shot region 81, since the supply amount of the gas 9 is small or the gas 9 is not supplied in step S202, the filling speed of the imprint material 7 to the pattern portion 5 is low. Therefore, as compared to the full shot region 80, the contact time between the imprint material 7 and the pattern portion 5 is increased in the partial shot region 81. At this time, the imprint material 7 applied in the region having the bend 2a or the step 2b can also contact the pattern portion 5, but the degree of contact can be insufficient for the entire imprint material 7 to remain on the substrate 2 upon releasing the mold. Thereafter, the controller 11 causes the light irradiator 20 to emit the ultraviolet light 21. The ultraviolet light 21 is applied to the imprint material 7 via the mold 4. This cures the imprint material 7 (curing step). In the partial shot region 81, since the supply amount of the gas 9 is small or the gas 9 is not supplied in step S202, the oxygen concentration in the space between the mold 4 and the imprint material 7 on the partial shot region 81 is high. The imprint material 7 in the portion where the pattern portion 5 contacts the partial shot region 81 is cured by the ultraviolet light 21 since the atmosphere disappears due to the contact. However, the imprint material 7 applied in the region having the bend 2a or the step 2b is in insufficient contact with the pattern portion 5 so that the atmosphere including oxygen exists around the imprint material 7. As has been described above, the imprint material 7 contains at least a polymerizable compound and a photopolymerization initiator. The imprint material 7 is cured by a polymerization reaction of the polymerizable compound caused by radicals generated from the photopolymerization initiator irradiated with the ultraviolet light 21. The oxygen reacts with the radicals generated from the photopolymerization initiator by irradiation with the ultraviolet light 21, and eliminates the radicals. This inhibits the polymerization reaction of the polymerizable compound. This means that the curing of the imprint material 7 is inhibited. Accordingly, the curing of the imprint material 7 applied in the region having the bend 2a or the step 2b is inhibited (suppressed) by oxygen in the atmosphere. If the gas 9 is not supplied in step S202, the oxygen concentration becomes higher so that and the effect of suppressing the curing of the imprint material 7 becomes greater.

In step S204, the controller 11 controls the mold holder 6 to separate (release) the pattern portion 5 from the cured imprint material 7 (separation step). At this time, since the imprint material 7 applied in the region having the bend 2a or the step 2b is in insufficient contact with the pattern portion 5, the imprint material 7′, which is a part of the imprint material 7, remains adhering to the pattern portion 5 upon releasing the mold. However, the remaining imprint material 7′ remains uncured since oxygen exists. If the amount of the remaining uncured imprint material 7′ is small, it will volatilize and disappear as the time elapses. Accordingly, no defect is generated in the imprint process on the next shot region.

In subsequent steps S205 to S207, the imprint process is performed on the full shot region 80. In step S205, the controller 11 controls the imprint material supply apparatus (not shown) to arrange (apply) the imprint material 7 in the full shot region 80 as the imprint target of the substrate 2 (apply step). At this time, the uncured imprint material 7′ remains on the pattern portion 5. After that, the controller 11 controls the substrate stage 3 to position the full shot region 80 with the imprint material 7 applied thereon below the pattern portion 5. Then, the controller 11 controls the gas supplier 10 to supply the gas 9 (supply step). With this, the air between the pattern portion 5 and the substrate 2 is replaced with the gas 9.

In step S206, the controller 11 controls the mold holder 6 to bring the pattern portion 5 into contact with the imprint material 7 on the full shot region 80 (contact step). With this, the imprint material 7 is filled in the pattern portion 5. In the contact step, the uncured imprint material 7′ remaining on the pattern portion 5 comes into contact with the imprint material 7 applied in the full shot region 80. Since both the imprint material 7′ and the imprint material 7 are in the uncured state, they are mixed and filled in the pattern portion 5. Since the gas 9 is supplied in step S205, the contact time can be shorter than in the contact step for the partial shot region 81 in step S203. Thereafter, the controller 11 causes the light irradiator 20 to emit the ultraviolet light 21. The ultraviolet light 21 is applied to the imprint material 7 via the mold 4. This cures the imprint material 7 (curing step).

In step S207, the controller 11 controls the mold holder 6 to separate (release) the pattern portion 5 from the cured imprint material 7 (separation step). Since the imprint material 7′ is mixed with the imprint material 7, no defect is generated in the contact portion of the remaining imprint material 7′.

The example has been described above in which, when performing the imprint process on the partial shot region, the supply amount of the gas by the gas supplier 10 is reduced as compared to the case of performing the imprint process on the full shot region. Next, an example will be described in which, when performing the imprint process on the partial shot region, the amount of irradiation light by the light irradiator 20 is increased as compared to the case of performing the imprint process on the full shot region.

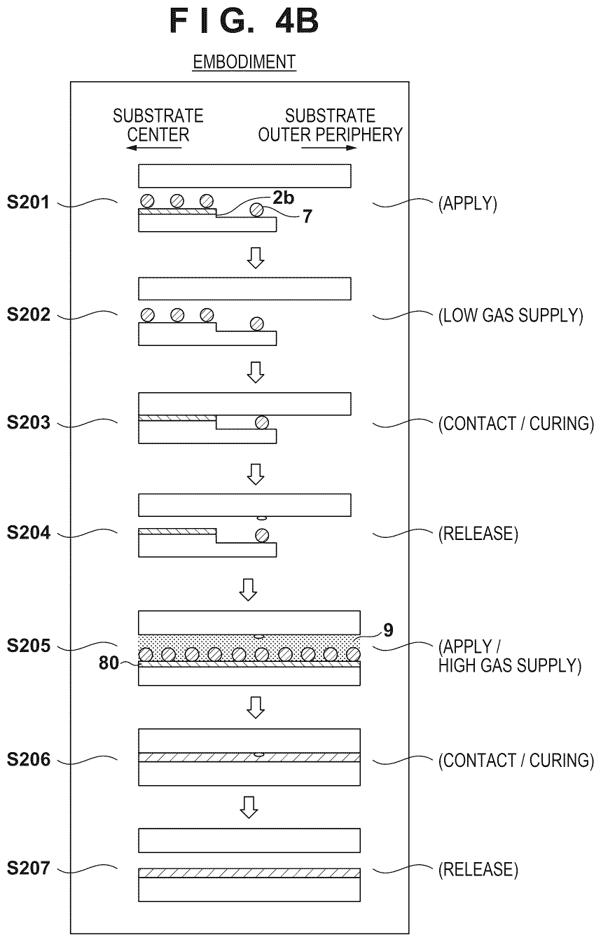

When the imprint process was performed on all the full shot regions 80 on the substrate 2 under a condition that the gas 9 was sufficiently supplied, a structure without pattern collapse as shown in a schematic sectional view of FIG. 5A was obtained. Then, the imprint process was performed on all the partial shot regions 81 on the substrate 2 while reducing the supply amount of the gas 9 as compared to the case of performing the imprint process on the full shot region 80, or without supplying the gas 9. In this case, as shown in a schematic sectional view of FIG. 5B, pattern collapse partially occurred, and this caused a variation in dimension of the imprinted structure in the region 81 compared to the region 80.

On the other hand, when the amount of irradiation light onto the partial shot region 81 was increased as compared to the amount of irradiation light onto the full shot region 80 and the imprint process was performed, a structure without pattern collapse as shown in the schematic sectional view of FIG. 5A was obtained. In order to decrease the variation in pattern dimension, for example, it is preferable to increase the amount of irradiation light onto the partial shot region 81 to 1.5 to 10 times the amount of irradiation light onto the full shot region 80. In order to minimize the variation in pattern dimension, it is more preferable to increase the amount of irradiation light onto the partial shot region 81 to 1.5 to 3 times the amount of irradiation light onto the full shot region 80.

As described above, in this embodiment, when performing the imprint process on the partial shot region, the supply amount of the gas from the gas supplier 10 is reduced and the amount of irradiation light from the light irradiator 20 is increased as compared to the case of performing the imprint process on the full shot region. This can achieve reduction of defects generated by the imprint process and reduction of a variation in pattern dimension.

### Second Embodiment

The second embodiment will be described below. Matters not mentioned in the second embodiment follow the first embodiment described above.

In the second embodiment, the imprint order for a plurality of shot regions on a substrate 2 will be described. As described in the first embodiment, the imprint process is performed on a full shot region 80 under the condition that a gas 9 is sufficiently supplied. On the other hand, the imprint process is performed on a partial shot region 81 while reducing the supply amount of the gas 9 as compared to that for the full shot region 80 and increasing the light irradiation amount as compared to that for the full shot region 80.

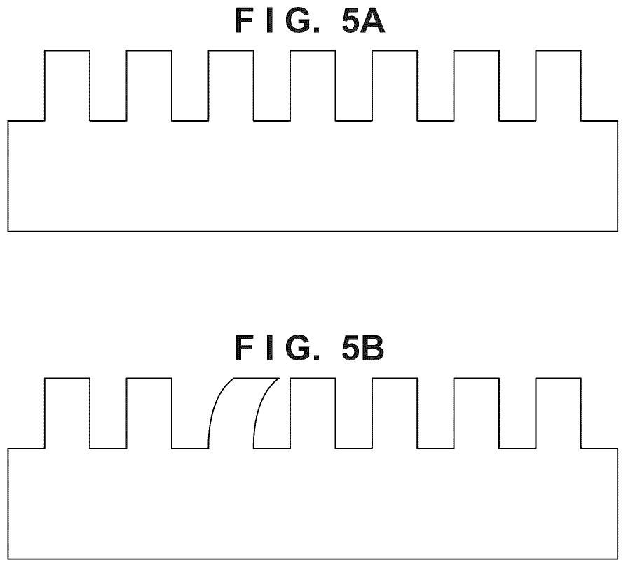

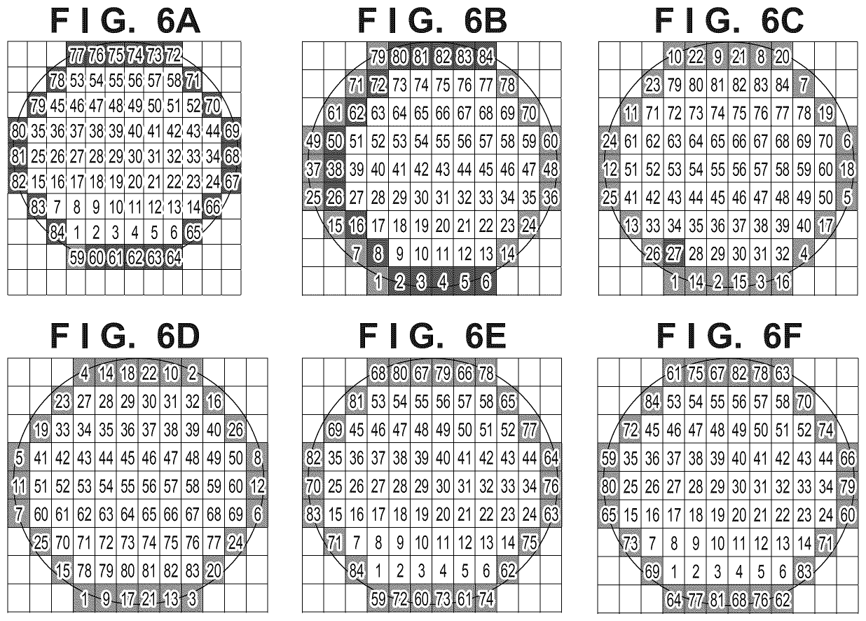

Experiments were carried out for the following six types of imprint orders. In FIGS. 6A to 6F, the numeric value attached to each of a plurality of shot regions indicates the imprint order. White shot regions indicate full shot regions, light gray shot regions indicate partial shot regions, and dark gray shot regions indicate shot regions where distortion occurred. FIG. 7 shows the number of shot regions where distortion occurred as a result of performing the imprint process in each imprint order.

### Imprint Order a: FIG. 6A

First, the imprint process was performed on the full shot regions in the order starting from the bottom left and proceeding from left to right and bottom to top. Then, the imprint process was performed on the partial shot regions in the order starting from the bottom left and proceeding from left to right and then bottom to top. As a result, out of 26 partial shot regions, thermal distortion occurred in 25 shot regions excluding the first partial shot region (the 59th shot region), and the overlay accuracy decreased. It can be seen that when the imprint process is performed consecutively on a partial shot region and an adjacent shot region, distortion occurs in the adjacent shot region.

### Imprint Order b: FIG. 6B

Without distinguishing the partial shot region and the full shot region, the imprint process was performed in the order starting from the bottom left shot region and proceeding from left to right and bottom to top. As a result, thermal distortion occurred in 17 shot regions, and the overlay accuracy decreased. It can also be seen here that when the imprint process is performed consecutively on a partial shot region and an adjacent shot region, distortion occurs in the adjacent shot region.

### Imprint Order c: FIG. 6C

First, the imprint process was performed on the partial shot regions in the order starting from the bottom left and skipping every other region. Then, the imprint process was performed on the full shot regions in the order starting from the bottom left and proceeding from left to right and bottom to top. Since the imprint process was performed consecutively on the 26th shot region, which is the final shot region of the partial shot regions, and the adjacent 27th shot region, which is the start shot region of the full shot regions, distortion occurred in the 27th shot region.

### Imprint Order d: FIG. 6D

First, the imprint process was performed on the partial shot regions in the order starting from the bottom left and non-contiguous between adjacent shot regions. Then, the imprint process was performed on the full shot regions in the order starting from the top left and proceeding from left to right and top to bottom. In this case, since the imprint process was not performed consecutively on the partial shot region and the adjacent shot region, no distortion occurred.

### Imprint Order e: FIG. 6E

First, the imprint process was performed on the full shot regions in the order starting from the bottom left and proceeding from left to right and bottom to top. Then, the imprint process was performed on the partial shot regions in the order starting from the bottom left and skipping every other region. Also in this case, since the imprint process was not performed consecutively on the partial shot region and the adjacent shot region, no distortion occurred.

### Imprint Order f: FIG. 6F

First, the imprint process was performed on the full shot regions in the order starting from the bottom left and proceeding from left to right and bottom to top. Then, the imprint process was performed on the partial shot regions in the order starting from the bottom left and non-contiguous between adjacent shot regions. Also in this case, since the imprint process was not performed consecutively on the partial shot region and the adjacent shot region, no distortion occurred.

As can be seen from the above, it is advantageous in terms of overlay accuracy to perform the imprint process on each of a plurality of shot regions in the order in which the imprint process is not performed consecutively on a partial shot region and an adjacent shot region.

### Third Embodiment

The third embodiment will be described below. Matters not mentioned in the third embodiment follow the first and second embodiments described above.

In this embodiment, the imprint process is performed on the full shot region under a condition that a gas 9 is sufficiently supplied. On the other hand, for the partial shot region, the supply amount of the gas 9 is reduced (the gas supply may be turned off) and the amount of irradiation light is increased as compared to the case of performing the imprint process on the full shot region. Furthermore, as in the second embodiment, the imprint process may be performed on each of the plurality of shot regions in the order in which the imprint process is not performed consecutively on a partial shot region and an adjacent shot region.

The imprint process was performed in the imprint order shown in FIG. 6B. That is, without distinguishing the partial shot region and the full shot region, the imprint process was performed in the order starting from the bottom left shot region and proceeding from left to right and bottom to top. If a distortion of 1 to 10 nm or more occurs per shot, the overlay accuracy decreases. Therefore, when performing the imprint process consecutively on adjacent shot regions, after the imprint process on one shot region, the process waits until the amount of thermal deformation of the substrate becomes 10 nm or less, and preferably 1 nm or less. After that, the imprint process is performed on the next shot region. At this time, when the waiting time before performing the imprint process on the full shot region and the waiting time before performing the imprint process on the partial shot region were set to be the same, the thermal deformation was large and distortion occurred. In contrast, when the waiting time before performing the imprint process on the partial shot region was set longer than the waiting time before performing the imprint process on the full shot region, the distortion was 10 nm or less, and the overlay accuracy improved.

Therefore, in this embodiment, when the imprint process is sequentially performed on a plurality of shot regions, a waiting time is provided before each imprint process. The waiting time before performing the imprint process on the partial shot region is preferably set longer than the waiting time before performing the imprint process on the full shot region. This provides further advantages in terms of overlay accuracy.

### Embodiment of Method of Manufacturing Article

The pattern of a cured product formed using an imprint apparatus is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile and nonvolatile semiconductor memories such as a DRAM, a SRAM, a flash memory, and a MRAM and semiconductor elements such as an LSI, a CCD, an image sensor, and an FPGA. Examples of the mold are molds for imprint.

The pattern of the cured product is directly used as at least some of the constituent members of the above-described articles or used temporarily as a resist mask. After etching or ion implantation is performed in the substrate processing step, the resist mask is removed.

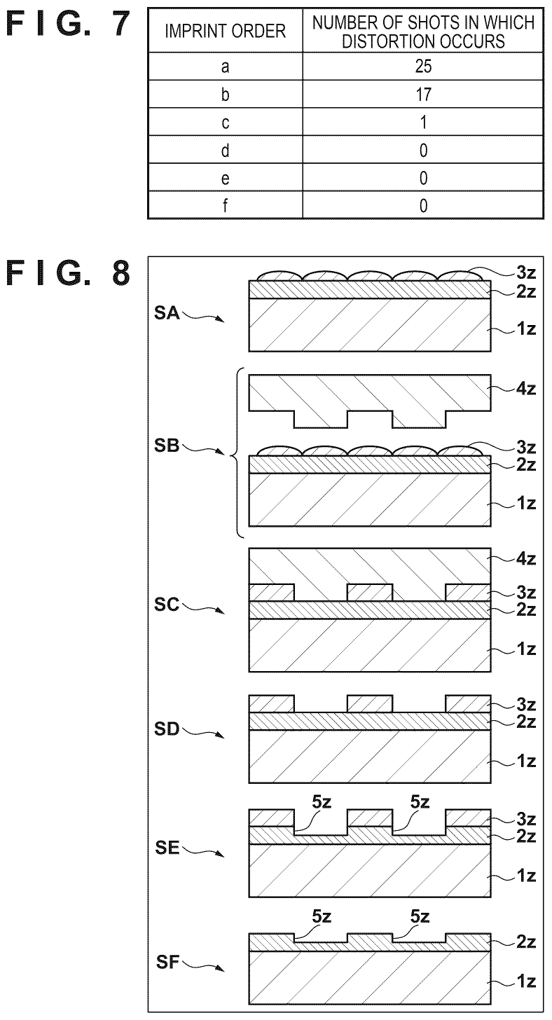

Referring to FIG. 8, a method of manufacturing an article will be described next. As shown step SA, a substrate 1z such as a silicon wafer with a processed material 2z such as an insulator formed on the surface is prepared. Next, an imprint material 3z is applied to the surface of the processed material 2z by an inkjet method or the like. A state in which the imprint material 3z is applied as a plurality of droplets onto the substrate is shown here.

As shown in step SB, a side of a mold 4z for imprint with an uneven pattern is directed toward and made to face the imprint material 3z on the substrate. As shown in step SC, the substrate 1z to which the imprint material 3z is applied is brought into contact with the mold 4z, and a pressure is applied. The gap between the mold 4z and the processed material 2z is filled with the imprint material 3z. In this state, when the imprint material 3z is irradiated with energy for curing via the mold 4z, the imprint material 3z is cured.

As shown in step SD, after the imprint material 3z is cured, the mold 4z is separated from the substrate 1z. Then, the pattern of the cured product of the imprint material 3z is formed on the substrate 1z. In the pattern of the cured product, the concave portion of the mold corresponds to the convex portion of the cured product, and the convex portion of the mold corresponds to the concave portion of the cured product. That is, the uneven pattern of the mold 4z is transferred to the imprint material 3z.

As shown in step SE, when etching is performed using the pattern of the cured product as an etching resistant mask, a portion of the surface of the processed material 2z where the cured product does not exist or remains thin is removed to form a groove 5z. As shown in step SF, when the pattern of the cured product is removed, an article with the grooves 5z formed in the surface of the processed material 2z can be obtained. Here, the pattern of the cured product is removed. However, instead of processing or removing the pattern of the cured product, it may be used as, for example, an interlayer dielectric film included in a semiconductor element or the like, that is, a constituent member of an article.

The present invention is not limited to the above embodiments and various changes and modifications can be made within the spirit and scope of the present invention. Therefore, to apprise the public of the scope of the present invention, the following claims are made.

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-001497, filed Jan. 9, 2024, which is hereby incorporated by reference herein in its entirety.

What is claimed is:

1. An imprint apparatus that performs, on each of a plurality of shot regions on a substrate, an imprint process of forming a pattern on a shot region by curing an imprint material by light irradiation while a mold is in contact with the imprint material on the shot region, comprising:
a supplier configured to supply a gas to a space between the mold and the imprint material on the shot region;
an irradiator configured to perform the light irradiation; and
a controller configured to control the supplier and the irradiator,
wherein
the plurality of shot regions include a full shot region having a size where a pattern region of the mold is fully transferred, and a partial shot region where only a part of the pattern region is transferred because of being located in an outer peripheral portion of the substrate, and
when performing the imprint process on the partial shot region, the controller reduces a supply amount of a gas from the supplier and increases an amount of irradiation light from the irradiator as compared to a case of performing the imprint process on the full shot region.

2. The apparatus according to claim 1, wherein the controller performs the imprint process on each of the plurality of shot regions in an order in which the imprint process is not performed consecutively on the partial shot region and a shot region adjacent thereto.

3. The apparatus according to claim 1, wherein the gas includes a permeable gas that is permeated through at least one of the mold and the imprint material.

4. The apparatus according to claim 1, wherein
reducing the supply amount of the gas from the supplier includes turning off supply of the gas from the supplier.

5. The apparatus according to claim 1, wherein when sequentially performing the imprint process on the plurality of shot regions, the controller provides a waiting time before each imprint process, and a waiting time before performing the imprint process on the partial shot region is set longer than a waiting time before performing the imprint process on the full shot region.

6. An imprint method of performing, on each of a plurality of shot regions on a substrate, an imprint process of forming a pattern of an imprint material by using a mold, wherein
the imprint process on one shot region includes
supplying a gas to a space between the mold and the imprint material on the shot region,
bringing the mold into contact with the imprint material on the shot region in a state in which the gas is supplied to the space, and
curing the imprint material by light irradiation in a state in which the imprint material is in contact with the mold,
the plurality of shot regions include a full shot region having a size where a pattern region of the mold is fully transferred, and a partial shot region where only a part of the pattern region is transferred because of being located in an outer peripheral portion of the substrate, and
when performing the imprint process on the partial shot region, a supply amount of the gas in the supplying is reduced and an amount of irradiation light of the light irradiation in the curing is increased as compared to a case of performing the imprint process on the full shot region.

7. The method according to claim 6, wherein the imprint process is performed on each of the plurality of shot regions in an order in which the imprint process is not performed consecutively on the partial shot region and a shot region adjacent thereto.

8. The method according to claim 6, wherein the gas includes a permeable gas that is permeated through at least one of the mold and the imprint material.

9. The method according to claim 6, wherein reducing the supply amount of the gas includes turning off supply of the gas.

10. The method according to claim 6, wherein when sequentially performing the imprint process on the plurality of shot regions, a waiting time is provided before each imprint process, and a waiting time before performing the imprint process on the partial shot region is set longer than a waiting time before performing the imprint process on the full shot region.

11. An article manufacturing method comprising:
forming a pattern on a substrate by using an imprint apparatus defined in claim 1; and
processing the substrate with the pattern formed thereon,
wherein an article is manufactured from the processed substrate.
